(19) United States
(12) Patent Application Publication
(10) Pub. No.: US 2026/0020184 A1
(43) Pub. Date: Jan. 15, 2026

(54) GAS INJECTION SYSTEM FOR IMMERSION COOLING

(71) Applicant: CGG Services SAS, Massy (FR)

(72) Inventor: Robbie Case, Houston, TX (US)

(73) Assignee: CGG Services SAS, Massy (FR)

(21) Appl. No.: 18/772,791

(22) Filed: Jul. 15, 2024

(51) Int. Cl. H05K 7/20

(52) U.S. Cl. CPC H05K 7/20236; H05K 7/20272

(57) ABSTRACT

A system for cooling electronic components in a cooling fluid immersion environment includes a container, a support, a conduit, and a pump. The container retains a first cooling fluid. The support suspends the electronic components in the container. The conduit transports the cooling gas into the container. The conduit includes an inlet section, a middle section, and an outlet section. The inlet section includes a conduit inlet positioned outside of the container. The outlet section includes outlets. The outlet section is submersed in the first cooling fluid within the container and beneath the electronic components such that the cooling gas exits the conduit and enters the first cooling fluid. The pump pressurizes and directs the cooling gas into and out of the conduit. The conduit is positioned downstream of the pump.

### BACKGROUND

Due to the ubiquitous nature of electronic systems such as computing devices, it is becoming increasingly common to house the computing devices in a primary storage location of a facility. This primary storage location may be referred to as a “data center,” and typically includes storage structures such as large racks or shelving units that serve to stack the computing devices in a vertical orientation. In this way, the storage structures create a clean and tidy environment necessary for a human operator to not trip or injure themselves on exposed computing devices.

However, it is commonly known that electronic systems generate heat during operation requiring removal to ensure that an adequate temperature range is maintained for the system. In conventional systems, heat is removed by running a fluid through the system to either exchange heat with another fluid externally, via an external cooling system, or to dissipate heat to the environment. A cooling system requiring less extensive external cooling systems is desirable to improve cooling performance of the system while reducing costs and minimizing potential failure points.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

A system for cooling electronic components in a cooling fluid immersion environment includes a container, a support, a conduit, and a pump. The container retains a first cooling fluid. The support suspends the electronic components in the container. The conduit transports the cooling gas into the container. The conduit includes an inlet section, a middle section, and an outlet section. The inlet section includes a conduit inlet positioned outside of the container. The outlet section includes outlets. The outlet section is submersed in the first cooling fluid within the container and beneath the electronic components such that the cooling gas exits the conduit and enters the first cooling fluid. The pump pressurizes and directs the cooling gas into and out of the conduit. The conduit is positioned downstream of the pump.

A method for cooling electronic components in a cooling fluid immersion environment includes retaining a first cooling fluid within a container. The method also includes suspending the plurality of electronic components in the container with a support. A cooling gas is circulated through a cooling system. A pump pressurizes and directs the cooling gas into a conduit inlet that is positioned outside of the container and downstream of the pump. In addition, the method includes transporting the cooling gas into the container with the conduit. The conduit includes an inlet section having the conduit inlet, a middle section, and an outlet section having outlets. The outlets are submersed in the first cooling fluid within the container and beneath the plurality of electronic components. The method further includes directing the cooling gas with the outlets such that the cooling gas exits the conduit through the outlets and enters the first cooling fluid.

Any combinations of the various embodiments and implementations disclosed herein can be used in a further embodiment, consistent with the disclosure. Other aspects and advantages of the claimed subject matter will be apparent from the following description and the claims.

### BRIEF DESCRIPTION OF DRAWINGS

Specific embodiments of the disclosed technology will now be described in detail with reference to the accompanying figures. Like elements in the various figures are denoted by like reference numerals for consistency. The sizes and relative positions of elements in the drawings are not necessarily drawn to scale. For example, the shapes of various elements and angles are not necessarily drawn to scale, and some of these elements may be arbitrarily enlarged and positioned to improve drawing legibility.

FIG. 1 depicts a system in accordance with one or more embodiments disclosed herein.

FIG. 2 depicts a system in accordance with one or more embodiments disclosed herein.

FIG. 3 depicts a system in accordance with one or more embodiments disclosed herein.

FIG. 4 depicts a system in accordance with one or more embodiments disclosed herein.

FIG. 5 depicts a system for circulating a cooling gas in accordance with one or more embodiments disclosed herein.

FIG. 6 depicts a system for circulating a cooling gas in accordance with one or more embodiments disclosed herein.

FIG. 7A-7C depict a system for circulating a cooling gas in accordance with one or more embodiments disclosed herein.

FIG. 8A-8D depict a system for circulating a cooling gas in accordance with one or more embodiments disclosed herein.

FIG. 9 depicts a flowchart of a process for cooling a plurality of electronic components in a cooling fluid immersion environment in accordance with one or more embodiments disclosed herein.

### DETAILED DESCRIPTION

In the following detailed description of embodiments of the disclosure, numerous specific details are set forth in order to provide a more thorough understanding of the disclosure. However, it will be apparent to one of ordinary skill in the art that the disclosure may be practiced without these specific details. In other instances, well-known features have not been described in detail to avoid unnecessarily complicating the description.

Throughout the application, ordinal numbers (e.g., first, second, third, etc.) may be used as an adjective for an element (i.e., any noun in the application). The use of ordinal numbers is not intended to imply or create any particular ordering of the elements nor to limit any element to being only a single element unless expressly disclosed, such as using the terms “before,” “after,” “single,” and other such terminology. Rather, the use of ordinal numbers is to distinguish between the elements. By way of an example, a first element is distinct from a second element, and the first element may encompass more than one element and succeed (or precede) the second element in an ordering of elements. Furthermore, while certain components are referred to in the singular to simplify discussion of embodiments of the invention, those skilled in the art will appreciate that any individual component (i.e., an electronic component) may be replaced with a multitude of components in advanced embodiments of the invention.

In addition, throughout the application, the terms “upper” and “lower” may be used to describe the position of an element of the invention. In this respect, the term “upper” denotes an element disposed above a corresponding “lower” element in a vertical direction, while the term “lower” conversely describes an element disposed below a corresponding “upper” element in the vertical direction.

In general, embodiments of the invention are directed towards a gas injection system using compressed gas to create a circulation flow thereof in an immersion cooling system. The system includes a container that retains a first cooling fluid and a support to suspend a plurality of electronic components in the container and the first cooling fluid. A system circulates a cooling gas that is pumped through a conduit at a static pressure, transporting the cooling gas into the container containing the first cooling fluid through supply ports or nozzles. An outlet section of the system that includes the supply ports or nozzles is submersed and located below the electronic components in the first cooling fluid within the container to allow the compressed gas to exit the conduit through the outlets, enter the first cooling fluid, and flow vertically upwards around the electronic components.

Embodiments of the invention are further directed towards a method for cooling electronic components in a cooling fluid immersion environment by retaining the first cooling fluid within the container, suspending the electronic components in the container with the support, and circulating the cooling gas through the system. The cooling gas is circulated by pressurizing and directing the cooling gas with a pump into the conduit inlet, transporting the cooling gas into the container through the conduit, and directing the cooling gas through outlets of the outlet section of the conduit that are submersed in the first cooling fluid within the container and beneath the electronic components.

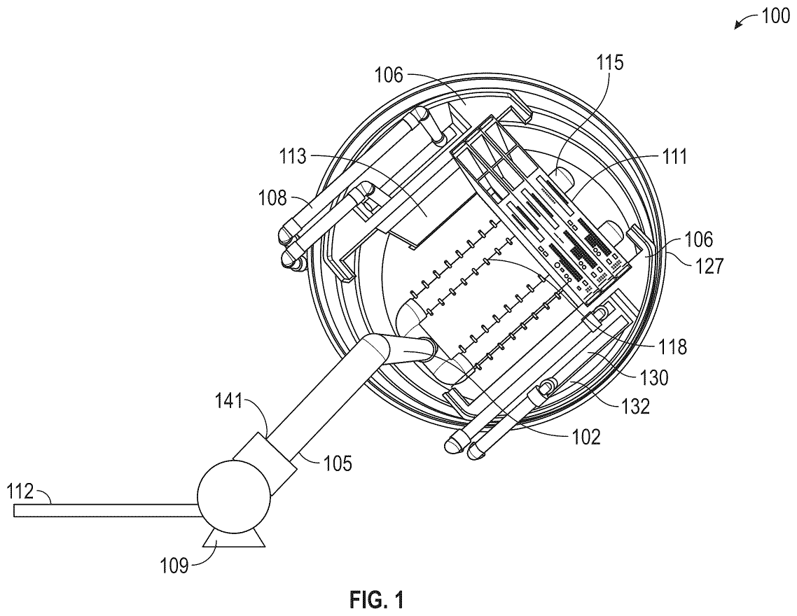

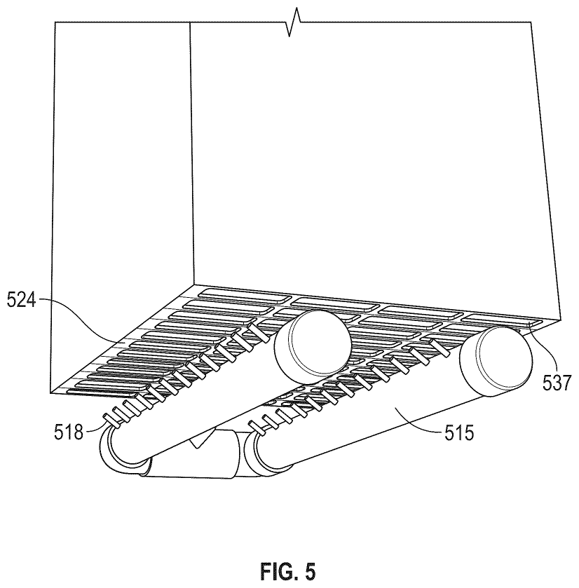

As shown in FIG. 1, the system 100 includes servers 111 situated within a container 127. The servers 111 may be embodied, for example, as blade servers or rack servers. The servers 111 are arranged within a server casing (e.g., FIG. 5) to position the servers 111 spatially in a specific configuration. The server casing may be a square prism or a rectangular prism. The bottom of the casing (e.g., FIG. 5) includes holes to allow cooling gas and the first cooling fluid to flow between and/or through the servers 111. In general, the servers 111 are computing devices or systems that provide network or cloud based services to connected devices (not shown) in a network (not shown) that includes the servers 111. Within the network (not shown), the servers 111 provide additional resources or functionality to the connected devices (not shown), such as performing computations, functions, or applications on behalf of or at the behest of the connected devices. Alternatively, or additionally, the servers 111 may provide data storage services to a connected device, or to facilitate communication between connected devices. However, the above description of the servers 111 is not intended to be all-encompassing, as servers 111 may perform additional functions such as security services or media sharing services. Although not depicted in FIG. 1, the servers 111 include components disposed on a circuit board (e.g., FIG. 5) thereof such as a microprocessor, a processing unit such as a Central Processing Unit (CPU) and/or a Graphics Processing Unit (GPU), one or more storage media (e.g., a Hard Disk Drive (HDD), a Solid State Drive (SDD), or Random Access Memory (RAM)), and a communication device (e.g., ethernet, Wi-Fi, or other Local Area Network (LAN) or Wide Area Network (WAN) interconnects) such as a transceiver that serves to transmit and receive signals from the connected devices.

The container 127 may be configured as a cylinder with an open top, and may be formed of a metal such as a chrome-molybdenum steel alloy, a vanadium steel alloy, a nickel steel alloy, or an equivalent metal. Alternatively, the container 127 may be formed of a plastic polymer such as polyvinyl chloride (PVC), high-density polyethylene (HDPE), nylon, or polystyrene, for example, and may take the form of a cube, rectangular prism, or other polyhedrons without departing from the nature of this disclosure.

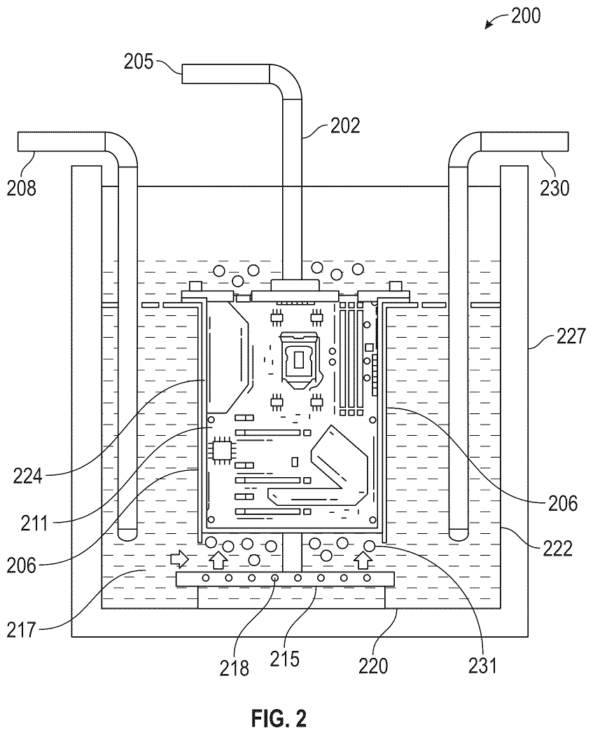

For its part, the support 106 serves to provide an internal structure of the container 127 that facilitates the positioning and orientation of various other components of the system 100 within the container 127. The support 106 includes an upper deck that forms a planar surface extending in a horizontal direction, and the upper deck is parallel to a bottom surface of the container 127. When the servers 111 are placed in the support 106, a connection face of the servers 111 abuts against the upper deck of the support 106, such that the remainder of the servers 111 are suspended and immersed in a first cooling fluid (e.g., FIG. 2).

The servers 111 generate a heat load as their components operate to provide the services described above. If a sufficiently large heat load is developed within the servers 111, the servers 111 may be detrimentally impacted, such as components of the servers 111 becoming de-soldered, semi-conductors (not shown) of the servers 111 not running at optimal efficiency due to the large heat load, or component burnout. Alternatively, the performance of the servers 111 may be throttled or bottlenecked to reduce the heat output of the server, where the heat output would otherwise cause delays or interruptions in the functionality of the servers 111 due to the repair or replacement of components damaged from the heat output. Thus, the container 127 contains a first cooling fluid (e.g., FIG. 2) surrounding at least part of the servers 111 so that the first cooling fluid (e.g., FIG. 2) absorbs heat from components of the servers 111. In one or more embodiments, the first cooling fluid (e.g., FIG. 2) may be dielectric oil (e.g., mineral oil) or water.

Due to the fact that the first cooling fluid (e.g., FIG. 2) is contained in the container 127, the first cooling fluid (e.g., FIG. 2) itself is only capable of redistributing the heat load from the servers 111 to the extremities of the container 127. That is, the first cooling fluid (e.g., FIG. 2) is not removed from the container 127 during the process of cooling the servers 111. Thus, to remove heat from the first cooling fluid (e.g., FIG. 2), the system 100 also includes a first pipe 108 and a second pipe 130 that each contain a second cooling fluid such as water or a similar non-volatile liquid. The first pipe 108 and second pipe 130 each include an in-line radiator disposed within the support 106. The first pipe 108 is connected to a first radiator 113, while the second pipe 130 is connected to a second radiator 132. The first pipe 108 and the second pipe 130 are coupled to pumps (not shown) that circulate the second cooling fluid through the conduits and to the first radiator 113 and the second radiator 132. The first radiator 113 and the second radiator 132 are at least partially immersed in the first cooling fluid (e.g., FIG. 2).

As shown in FIG. 1, the first pipe 108 and the second pipe 130 each pass through an opening of the support 106 to connect to the first radiator 113 and the second radiator 132, respectively. Thus, when the water is circulated through the pipes in the portion of the pipes immersed in the first cooling fluid (e.g., FIG. 2), the first cooling fluid (e.g., FIG. 2) transfers heat through the first pipe 108 and the second pipe 130 to the second cooling fluid, which is circulated out of the system 100. In this way, heat is removed from the container 127 and the components contained therein by the first pipe 108 and the second pipe 130, and is transported out of the system 100.

The system for circulating the cooling gas through the system includes an auxiliary section 112 providing the cooling gas to the pump 109. In one or more embodiments, the cooling gas contains nitrogen, oxygen, or both. One or more alternative cooling gases that are chemically inert to and may thus be emulsified with the first cooling fluid (e.g., FIG. 2) may be utilized without departing from the nature of this specification. In one or more embodiments, the pump 109 may be a compressor or a centrifugal pump. The pump 109 is directly connected to the auxiliary section 112 and the inlet section 105. The pump 109 is powered by an auxiliary power source (not shown) and operates to pressurize the first cooling fluid 117 and deliver the first cooling fluid 117 to the inlet section 105. The location of the pump 109 exterior to the container 127 ensures that the pump 109 is easily accessed for maintenance or other necessary modifications.

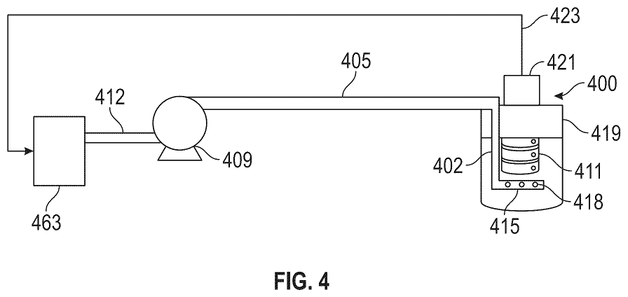

In one or more embodiments, the auxiliary section 112 directs cooling gas from a storage tank (e.g., FIG. 4) positioned upstream of the auxiliary section 112 to the container 127. The inlet section 105 of the conduit directs the pressurized cooling gas from the pump 109, through the middle section 102, and to the outlet section 115. Directionally, the middle section 102 of the conduit extends orthogonally to a primary extension direction of the inlet section 105 and a primary extension direction of the outlet section 115. As shown in FIG. 1, the inlet section 105 includes a conduit inlet 141. The conduit inlet 141 is an inlet orifice of the conduit forming the inlet section 105, and is positioned outside of the container 127 and connected to the pump 109. The outlet section 115 is submersed in the first cooling fluid (e.g., FIG. 2) within the container 127 and beneath the servers 111. The cooling gas enters the first cooling fluid (e.g., FIG. 2) through the nozzles 118 in the outlet section 115, emulsifying the cooling gas in the first cooling fluid (e.g., FIG. 2). Emulsification creates turbulence within the first cooling fluid, promoting effective heat exchange between the cooling gas and the first cooling fluid. Additionally, emulsification may change the heat capacity and/or viscosity of the first cooling fluid, also promoting cooling of the first cooling fluid. In one or more embodiments, the nozzles 118 are through orifices with a conical or cylindrical profile. In other embodiments, the nozzles 118 may be a bell, parabolic, or a cylindrical profile with a rounded nose at the outlet. A size of the nozzles may impact the pressure and volume of cooling gas.

FIG. 2 depicts a front view of a system 200 including servers 211, a container 227, a support 206, a first pipe 208, a server casing 224, and a second pipe 230. The support 206 abuts against a bottom surface 220 and a sidewall 222 of the container 227, and is retained within the container 227 under the force of gravity. The container 227 retains, with the bottom surface 220 and the sidewall 222, a volume of a first cooling fluid 217 such that the support 206 is depicted as being partially immersed in the first cooling fluid 217. In other embodiments, the support 206 may be fully immersed in the first cooling fluid 217. The portion of the support 206 immersed in the first cooling fluid 217 is a function of the above mentioned system 200 characteristics of a heat transfer rate of the system, the size of the container 227, and budgeting and/or material constraints, for example. The support 206 suspends the servers 211 housed within the server casing 224 above the outlet section 215 such that the cooling gas 231 flows vertically through the first cooling fluid 217 and around the servers 211. The server casing 224 envelopes the servers 211 in such a way as to position the servers 211 within the container 227. The server casing 224 may include a tab at the top end, as shown in FIG. 2, to rest on the support 206 and provide additional stability for the servers 211.

To facilitate removal of the heat produced by the heat generating components of the servers 211, the cooling gas 231 is provided through the inlet section 205. The cooling gas 231 flows from the inlet section 205 through the middle section 202 and to the outlet section 215, where it flows from the nozzles 218 into the first cooling fluid 217, emulsifying the cooling gas 231 in the first cooling fluid 217. The cooling gas 231 is dispersed in the first cooling fluid 217, as it flows upwards, between, and around the servers 211 to the surface of the first cooling fluid 217, reducing the temperature of the first cooling fluid 217 and improving its capacity to absorb heat from the servers 211. In other words, as the first cooling fluid 217 is cooled by the cooling gas 231, the lower temperature of the first cooling fluid 217 allows the first cooling fluid 217 to absorb additional heat from the servers 211, which is, in turn, cooled from the cooling gas 231 in a cyclical process. Thus, the cooling capabilities of the first cooling fluid 217 on the servers 211 improve as the cooling gas 231 is emulsified into the first cooling fluid 217. It is noted that the cooling gas 231 is depicted as gas bubbles for the sake of visual clarity and distinction from the first cooling fluid 217, but the size, shape, and number of the bubbles is not intended to confer physical characteristics of any portion of the system 200.

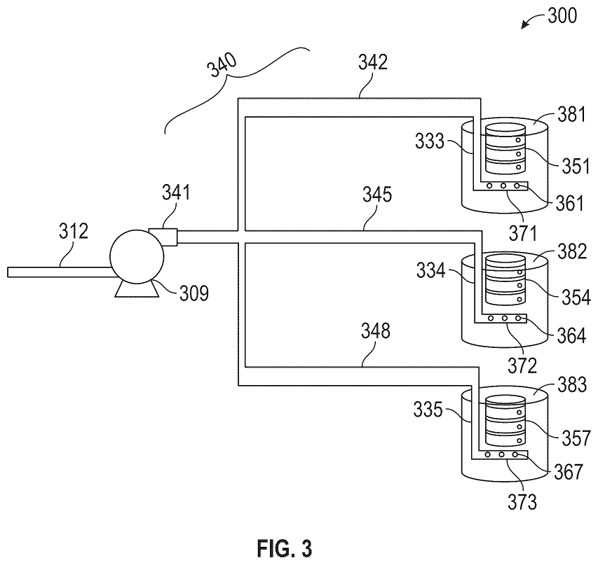

In one or more embodiments, multiple servers are configured in a parallel arrangement in the system 300. Any number of servers may be arranged in a parallel configuration similar to that illustrated in FIG. 3, such that the supply of cooling gas is sufficient to meet the volumetric flow rate requirements for cooling. Turning to FIG. 3, an example is illustrated using three containers of servers in parallel. An auxiliary section 312 of the conduit provides the cooling gas to the pump 309. The system 300 further includes a pump 309, an inlet section 340, three middle sections (333, 334, 335), three outlet sections (371, 372, 373), and three sets of nozzles (361, 364, 367).

The inlet section 340 includes a conduit inlet 341, a first branch 342, a second branch 345, and a third branch 348. In some arrangements, the inlet section 340 may include a singular conduit inlet 341, as is illustrated in FIG. 3, with multiple branches (342, 345, 348). In other multiple container arrangements with more than one pump (not shown), the inlet section may include multiple conduit inlets exiting each of the pumps in addition to the multiple branches. In these arrangements (not shown), the inlet section is immediately downstream of the pump(s), the middle sections are downstream of the inlet section, and the outlet sections are downstream of the middle sections.

Cooling gas flows through the first nozzles 361 in the first outlet section 371 to cool the first servers 351 within the first container 381. The cooling gas is provided to the first outlet section 371 through the inlet section 340 and the first middle section 333. In parallel, cooling gas flows through the second nozzles 364 in the second outlet section 372 to cool the second servers 354 within the second container 382. The cooling gas is provided to the second outlet section 372 through the inlet section 340 and the second middle section 334. Also in parallel, cooling gas flows through the third nozzles 367 in the third outlet section 373 to cool the third servers 357 within the third container 383. The cooling gas is provided to the third outlet section 373 through the inlet section 340 and the third middle section 335. The inlet section 340 is sized and shaped based upon the location of the containers in the system 300. For example, the multiple containers (381, 382, 383) do not need to be in close proximity to each other nor in close proximity to the pump(s), as the only system components required to be adapted for differing facility layouts is the structure of the inlet section 340. That is, the middle sections 333-335, outlet sections 371-373, containers, and servers 351, 354, 357 may have the same dimensions regardless of their proximity to each other. In other embodiments, the containers may be closely arranged to reduce the length of the inlet section 340.

As discussed above, the cooling gas flows upwards through the first cooling fluid through the container around the server. When the cooling gas is released at the surface of the first cooling fluid, it may release into the environment if the container is open to the environment; however, in some embodiments, the container may not be open to the environment and may instead be a closed system. To avoid over pressurization of the container as cooling gas is released at the surface of the first cooling fluid, a ventilation hood may be present on a lid sealing the top end of the container to capture the cooling gas, as is illustrated in FIG. 4. In the embodiment illustrated in FIG. 4, the ventilation hood 421 is present on the lid 419 of the container containing the servers 411, and may apply negative pressure to remove the cooling gas from the space above the first cooling fluid and recycle the cooling gas to the reservoir 463. In one or more embodiments, the reservoir 463 is a storage tank sized and shaped to retain an appropriate volume of recycled cooling gas. The recycled cooling gas flows into the reservoir 463, which is used as a source for cooling gas that is pulled from the auxiliary section 412 using the pump 409. The cooling gas is then pumped at a static pressure, to allow for even flow, through the inlet section 405 to the middle section 402 and to the outlet section 415 containing nozzles 418, releasing the cooling gas into the first cooling fluid. In one or more embodiments, the static pressure required and volumetric flow rate of the cooling gas is based on a diameter of the conduit and the nozzle size.

FIG. 5 provides a closer view of the outlet section 515 containing the nozzles 518 situated underneath the servers 511 held in the server casing 524. In this embodiment, the nozzles 518 are situated at a 45-degree angle relative to a horizontal plane through a centerline of the outlet section 515. The angle of the nozzle impacts the trajectory of the flow of the cooling gas through the first cooling fluid, impacting the capacity of the first cooling fluid to absorb heat. The server casing 524 contains holes 537 in the bottom surface of the casing, allowing the first cooling fluid 217 and the cooling gas to flow between the servers 511 within the server casing 524. The server casing 524 vertically positions the servers 511 within the first cooling fluid (not shown).

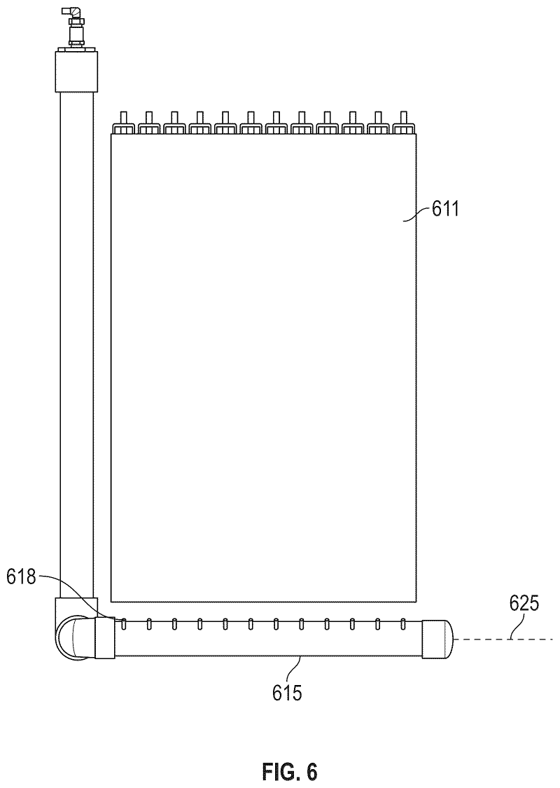

FIG. 6 provides a side view of the outlet section 615 containing the nozzles 618 situated underneath the servers 611. There is an extension plane 625 illustrated to provide a reference point for describing nozzle angle. In this embodiment, the nozzles 618 are situated at a 45 degree angle relative to the extension plane 625.

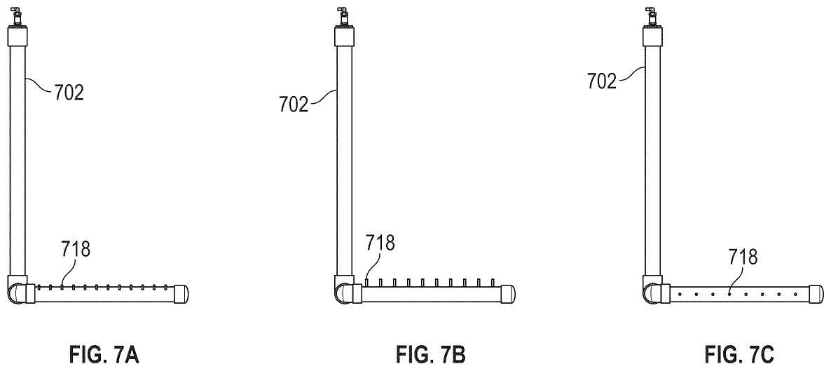

While the nozzles in FIGS. 5 and 6 are both illustrated at a 45 degree angle relative to the extension plane 625, the nozzles may be situated at any angle between 0 and 90 degrees relative to the extension plane 625. Turning to FIGS. 7A-7C, the nozzles 718 are illustrated in three positions. In FIG. 7A, the nozzles 718 are at a 45 degree angle relative to the extension plane 625, similar to the arrangement of FIGS. 5 and 6. In FIG. 7B, the nozzles 718 are situated at a 90 degree angle relative to the extension plane 625. In FIG. 7C, the nozzles are coplanar, or at a 0 degree angle, with the extension plane 625. The optimum position of the nozzles 718 may be determined, for example, based on various characteristics including server size, server position, type of cooling fluid, and type of cooling gas. For example, arrangements similar to that illustrated in FIG. 7C may be useful for creating a wider area of emulsification, while arrangements similar to FIG. 7B may be useful for creating a narrower area of emulsification. Arrangements similar to that of FIG. 7A may be a balance between the two emulsification areas. Wider areas may be useful for addressing wide area cooling while narrower areas may be more useful at addressing hot spots.

In addition to the above referenced characteristics, the position of the nozzles 718 may be related to the orientation of the outlet section of the conduit. The orientation of the outlet section of the conduit may be based on a heat characteristic, such as a maximum thermal output of the servers, a predetermined heat load to be removed from the servers, or a specific heat load to be removed from each server.

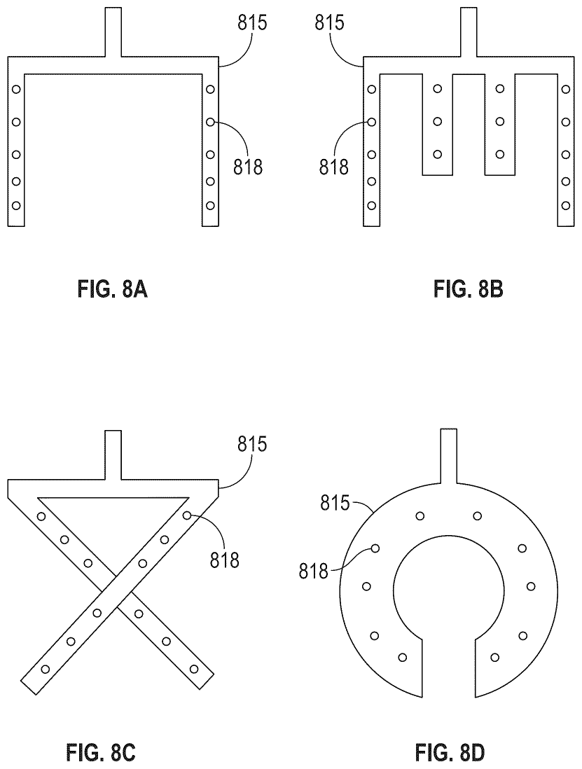

As shown in FIGS. 8A-8D, the outlet section 815 of the conduit containing nozzles 818 may be orientated in a variety of different arrangements. Though not limited to only those illustrated in FIGS. 8A-8D, these figures represent examples of several of these possible orientations of the outlet section 815. In FIG. 8A, the outlet section 815 is orientated as two parallel segments of the conduit, similar to FIG. 5. FIG. 8B illustrates a different orientation of the outlet section 815, with two parallel segments having a first length and two parallel segments having a second length that is shorter than the first length. FIG. 8B shows the shorter length segments in between the longer length segments, though this is not required. In one or more embodiments, the longer segments may be in between the shorter segments. In other embodiments, the segment length may alternate between longer and shorter segments. FIG. 8C illustrates an orientation where each of the segments of the outlet section 815 cross. In one or more embodiments, the segments form a perpendicular, 90-degree angle. Other angles may be utilized such that the segments meet at a common point (i.e., a triangle configuration), or to form a shallow shared angle greater than 90 degrees for compact cooling. FIG. 8D illustrates an orientation of the outlet section 815 where the segments of the outlet section 815 are rounded. These rounded segments may be in a partial or complete circle or oval shape.

The outlet section 815 may include additional segments or orientations in addition to those illustrated in FIGS. 8A-8D without departing from the nature of this specification, and FIGS. 8A-8D serve to present a selection of representative examples of the configuration of the outlet section 815 rather than an exhaustive list thereof.

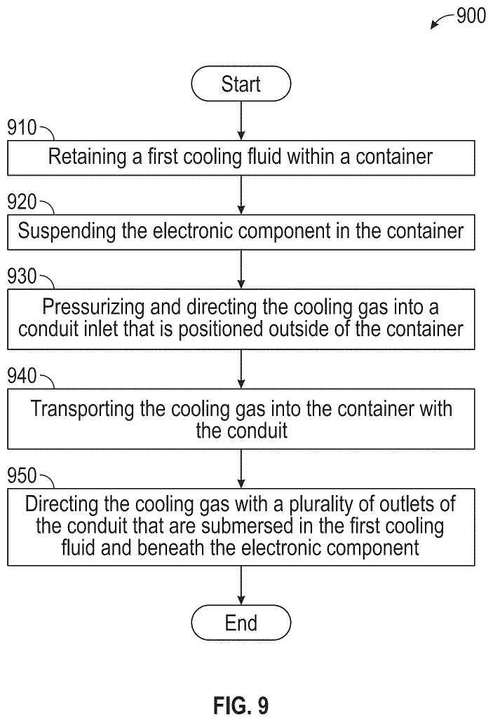

Turning to FIG. 9, FIG. 9 depicts a method 900 for cooling electronic components in a cooling fluid immersion environment consistent with one or more embodiments disclosed herein. Steps of FIG. 9 may be performed by a system 100 as described herein, but are not limited thereto. Furthermore, the steps of FIG. 9 may be performed in any order, such that the steps are not limited to the sequence presented. In addition, multiple steps of FIG. 9 may be performed as a single action, or one step may comprise multiple actions by systems or components described herein.

The method 900 initiates with step 910, which includes retaining a first cooling fluid 217 within a container 127. In step 920, the electronic components are suspended in the container 127 with a support 106. In one or more embodiments, the electronic components include servers 111. The support 106 may be a 3D printed structure that includes various channels that serve to direct a fluid flow through the support 106 and the servers 111. The first cooling fluid 217 is retained within the container 127 such that the support 106 is either fully or partially immersed in the first cooling fluid 217. As the first cooling fluid 217 flows through the servers 111, the first cooling fluid 217 absorbs heat from components of the servers 111, and moves the heat to a different location of the support 106 to be removed from the system 100 entirely. In one or more embodiments, a second cooling fluid is directed through a first pipe 108 and a second pipe 130 to circulate through a first radiator 113 and a second radiator 132 immersed in the first cooling fluid 217 to remove heat from the first cooling fluid 217. Because of the emulsion formed between the cooling fluid and the cooling gas, standardized heatsink fins may be suitable for the first and second radiators.

Steps 930 to 950 describe a process of circulating a cooling gas 231 through the system. In step 930, the cooling gas 231 is pressurized using a pump 109 and directed into a conduit inlet, downstream of the pump 109, that is positioned outside of the container 127. In step 940, the cooling gas 231 is transported into the container 127 through the conduit, which contains an inlet section 105, a middle section 102, and an outlet section 115 including outlets. In one or more embodiments, the outlets are nozzles 118. In Step 950, the cooling gas 231 is directed with the outlets of the outlet section 115 that are submersed in the first cooling fluid 217 within the container 127 and beneath the servers 111. The cooling gas 231 exits the conduit through the nozzles 118 and enters the first cooling fluid 217. When the cooling gas 231 enters the first cooling fluid 217, the cooling gas 231 is emulsified in the first cooling fluid 217.

In one or more embodiments, the system 100 may include multiple containers with servers, such as that illustrated in FIG. 3. In these embodiments, the method may be modified such that a single pump may pressurize and direct the cooling gas into multiple conduit inlets and out of multiple outlet sections containing nozzles in parallel simultaneously. Alternatively, multiple pumps may be connected to multiple conduit inlets such that the inlet section and outlet section of the system are formed as manifolds or plenums connecting the pumps to the containers.

Embodiments of the present disclosure may provide at least one of the following advantages. The system for cooling electronic components in a cooling fluid immersion environment provides a cooling mechanism for the first cooling fluid around and between servers to ensure heat is able to be continually removed from the servers without the first cooling fluid exiting the container. The simplicity of design reduces potential failures associated with the more conventional approach of using external heat exchangers to circulate the first cooling fluid outside of the container.

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims.

What is claimed is:

1. A system for cooling a plurality of electronic components in a cooling fluid immersion environment, the system comprising:
a container configured to retain a first cooling fluid;
a support configured to suspend the plurality of electronic components in the container;
a conduit configured to transport a cooling gas into the container, the conduit comprising an inlet section, a middle section, and an outlet section, and
a pump configured to pressurize and direct the cooling gas into and out of the conduit, where the conduit is disposed downstream of the pump,
wherein the inlet section comprises a conduit inlet and the outlet section comprises a plurality of outlets;
wherein the conduit inlet is positioned outside of the container, and the outlet section is submersed in the first cooling fluid within the container and beneath the plurality of electronic components such that the cooling gas exits the conduit and enters the first cooling fluid.

2. The system of claim 1, wherein the first cooling fluid comprises mineral oil.

3. The system of claim 1, wherein the plurality of electronic components is a plurality of blade servers or a rack servers.

4. The system of claim 1, wherein the cooling gas is nitrogen, oxygen, or a combination thereof.

5. The system of claim 1, wherein the plurality of outlets comprise conical nozzles.

6. The system of claim 5, wherein the conical nozzles are angled between 0 and 90 degrees relative to an extension plane of the outlet section of the conduit.

7. The system of claim 1, further comprising a storage tank upstream of the pump configured to provide a source of the cooling gas.

8. The system of claim 1, wherein the plurality of outlets are configured to emulsify the cooling gas with the first cooling fluid.

9. The system of claim 1, wherein the support suspends the plurality of electronic components directly above the plurality of outlets of the conduit such that the cooling gas flows vertically through the first cooling fluid and around the plurality of electronic components.

10. The system of claim 1, wherein the middle section of the conduit extends in a direction orthogonal to an extension direction of the inlet section and an extension direction of the outlet section.

11. The system of claim 1, wherein an orientation of the outlet section of the conduit is configured based upon a heat characteristic, wherein the heat characteristic comprises: a maximum thermal output of a plurality of servers, a predetermined heat load to be removed from the plurality of servers as a whole, or a specific heat load to be removed from each server of the plurality of servers.

12. The system of claim 11, wherein the orientation of the outlet section of the conduit comprises at least two parallel segments of the conduit.

13. The system of claim 11, wherein the orientation of the outlet section of the conduit comprises at least two rounded segments of the conduit.

14. The system of claim 11, wherein the orientation of the outlet section of the conduit comprises a first set of segments comprising at least two parallel segments having a first length, and a second set of segments comprising at least two parallel segments having a second length that is shorter than the first length.

15. The system of claim 1, further comprising:
a second outlet section configured to provide the first cooling fluid through second nozzles to cool a second server; and
a third outlet section configured to provide the first cooling fluid through third nozzles to cool a third server.

16. The system of claim 7, further comprising a ventilation hood positioned on a lid sealing a top end of the container, wherein the ventilation hood is configured to recycle the cooling gas exiting the first cooling fluid to the storage tank.

17. A method for cooling a plurality of electronic components in a cooling fluid immersion environment, the method comprising:
retaining a first cooling fluid within a container;
suspending the plurality of electronic components in the container with a support, and
circulating a cooling gas through a cooling system in a cooling fluid immersion environment with a conduit;
pressurizing and directing the cooling gas, with a pump, into a conduit inlet that is positioned outside of the container, where the conduit is disposed downstream of the pump,
transporting the cooling gas into the container with the conduit, the conduit comprising an inlet section comprising the conduit inlet, a middle section, and an outlet section comprising a plurality of outlets;
directing the cooling gas with the plurality of outlets of the outlet section that are submersed in the first cooling fluid within the container and beneath the plurality of electronic components such that the cooling gas exits the conduit through the plurality of outlets and enters the first cooling fluid.

18. The method of claim 17, further comprising emulsifying the cooling gas with the first cooling fluid.

19. The method of claim 17, further comprising:
providing the first cooling fluid through a second outlet section comprising second nozzles to cool a plurality of second servers; and
providing the first cooling fluid through a third outlet section comprising third nozzles to cool a plurality of third servers.

20. The method of claim 17, further comprising recycling the cooling gas exiting the first cooling fluid to a storage tank through a ventilation hood positioned on a lid sealing a top end of the container.
